(19) United States
(12) Patent Application Publication
(10) Pub. No.: US 2010/0056231 A1
(43) Pub. Date: Mar. 4, 2010

(54) Housing for Hand-Held Device with Extruded Element having Area of Bulk Material and Corresponding Method

(75) Inventors: Gary R. Weiss, Buffalo Grove, IL (US); Joseph L. Allore, Mundelein, IL (US); Jason P. Wojack, Libertyville, IL (US)

Correspondence Address: MOTOROLA INC, 600 NORTH US HIGHWAY 45, W4 - 39Q, LIBERTYVILLE, IL, 60048-5343, US

(73) Assignee: MOTOROLA INC, Libertyville, IL (US)

(21) Appl. No.: 12/269,589

(22) Filed: Nov. 12, 2008

Related U.S. Application Data
(60) Provisional application No. 61/093,320, filed on Aug. 30, 2008.

(51) Int. Cl. H05K 7/00; H04M 1/00; H01S 4/00

(52) U.S. Cl. 455/575.1; 361/679.01; 29/592.1

(57) ABSTRACT

A housing for a hand-held electronic device and a corresponding method for forming the same are provided. The housing includes an extruded element having a profile corresponding to a cross-section of the element, which is perpendicular to the direction of extrusion, where the extruded element includes within the profile, one or more areas of bulk material. The one or more areas of the bulk material include a machined surface along the length of the extruded element in the direction of the extrusion including a resulting machined profile. The resulting machined profile varies along the length of the extruded element in the direction of extrusion, while maintaining the continuity of the formed surface.

### CROSS REFERENCE TO RELATED APPLICATIONS

This application claims priority from a U.S. Provisional Patent Application Ser. No. 61/093,320, filed Aug. 30, 2008.

### FIELD OF THE INVENTION

The present invention relates generally to a housing for a hand-held electronic device and a method for forming the same, and more particularly, to a housing having an extruded element including a profile with one or more machinable areas.

### BACKGROUND OF THE INVENTION

Hand-held electronic devices have often been made from two separately formed halves of a housing, a front half and a back half, which are coupled together with one or more fasteners, within which the electrical and mechanical components forming the device are placed. Often times, each of the front half and the back half are formed from plastic or other material using an injection molding process, which enables considerable freedom in incorporating diverse sizes and shapes, and which can be used to produce various functional and/or aesthetic effects. Generally, the desired sizes and shapes, and their corresponding arrangement are incorporated into the shape of a mold. The mold is then used to produce the parts.

More recently an increasing amount of housings are being seen, which are being made from materials other than plastics, such as various metals and metal alloys, where the use of metal materials have often been accompanied by still further manufacturing techniques for similarly producing separately formed halves, which are then coupled together. In the case of metals and metal alloys, various techniques including forging, and/or stamping and forming have often been used to produce components used in forming the housings.

The movement toward an increasing amounts of metal in the housings has been precipitated in part due to the decrease in the overall size of devices, while the size of displays, keypads, and other components have alternatively increased in size. This has resulted in less material (i.e. reduced device volume) being used in the formation of the housing, as well as the support structures within and/or forming part of the housing. Correspondingly, the material used to form the housing and/or the corresponding support structures have had to be formed from stronger materials able to withstand an ever increasing load per unit measure. This in turn has facilitated the increasing use of manufacturing processes, which are consistent with the more recently predominant materials being used.

With molded, forged and stamped parts, tooling used in economically producing large volumes of the parts tends to be very specific to a particular design, such that if changes need to be made to the design, often times corresponding changes need to made to the associated tooling. For example, if the parts which are being molded need to be changed, the mold from which the parts are produced would often similarly need to be changed. In some instances, an existing mold might be able to be modified to accommodate a particular change. In other instances, new molds might need to be produced.

Some manufacturing processes for housings for use in hand-held electronic devices have more recently involved the use of extruded materials. Extruded materials typically involve a manufacturing method where an amount of material is pushed or drawn through a die, thereby producing a formed element, which has a generally uniform profile at varying points along the length of the extruded element in the direction of extrusion. More specifically, the formed element generally has a uniform cross sectional shape which is defined by the size and the shape of the openings in the die through which material is pushed or drawn. In addition to using the die to define the outer cross sectional shape, hollow sections within the shape can similarly be formed, for example, by placing a pin or piercing mandrel inside the die. Traditionally, extrusions have been used in applications where an element having long, straight and generally uniform shapes are desired. For elements having significant variations along the length of the element, extrusions have typically been avoided.

Recent extruded elements used in the formation of a housing have included an extrusion having a one piece continuous outer profile, which is used to form each of the front, back and sides of the device. Such a construction can result in enhanced structural strength, in so far as the front, back and sides are formed as part of a one piece construction. A hollow section is formed in the extruded element having an opening at the beginning and end of the extrusion, often corresponding to a top and bottom, within which mechanical and electronic components can be placed. In some instances openings will be cut into the sidewall of the extruded element along the length of the same to provide more direct access to some of the internally placed and appropriately aligned mechanical and electronic components. After the components have been placed within the housing, the openings at the ends of the extrusion are generally capped.

In such an instance, the appearance of the housing is generally very uniform (i.e. generally does not vary) along the length of the extrusion. To date, such a construction has resulted in housings which have very limited amounts of variability along the length of the extrusion. While such a style can be very clean and uniform, sometimes such a style can be very plain. In some instances, it can be very difficult to deviate from such a style even when function and/or aesthetics would prefer such a deviation, which limits the type of housings that have historically been produced through such a manufacturing process.

Consequently, the present inventors have recognized that it would be beneficial if a housing could be developed incorporating an extruded element, which allows for variability in the cross-sectional profile along the length of the extrusion.

### SUMMARY OF THE INVENTION

The present invention provides a housing for a hand-held electronic device. The housing includes an extruded element having a profile corresponding to a cross-section of the element, which is perpendicular to the direction of extrusion. The extruded element includes within the profile, one or more areas of bulk material. The one or more areas of the bulk material include a machined surface along the length of the extruded element in the direction of the extrusion including a resulting machined profile. The resulting machined profile varies along the length of the extruded element in the direction of extrusion, while maintaining the continuity of the formed surface.

In at least one embodiment, the one or more areas of bulk material include an area of bulk material positioned within the profile at one or more ends of the major axis and extends in the direction of the minor axis.

In at least a further embodiment, the one or more areas of bulk material include an area of bulk material positioned within the profile at one or more ends of the minor axis, which extend in the direction of the major axis.

The present invention further provides a hand-held electronic device including a housing. The housing of the hand-held electronic device includes an extruded element having a profile corresponding to a cross-section of the element, which is perpendicular to the direction of extrusion. The extruded element includes within the profile, one or more areas of bulk material. The one or more areas of the bulk material include a machined surface along the length of the extruded element in the direction of the extrusion including a resulting machined profile. The resulting machined profile varies along the length of the extruded element in the direction of extrusion, while maintaining the continuity of the formed surface.

The present invention still further provides a method for forming a housing for a hand-held electronic device. The method includes extruding an element having a profile corresponding to a cross-section of the element, which is perpendicular to the direction of extrusion, where within the profile, one or more areas of bulk material are included. The bulk material included within the profile of the extruded element is then machined along the length of the extruded element, such that the resulting machined profile varies along the length of the extruded element in the direction of the extrusion, while maintaining the continuity of the formed surface.

### BRIEF DESCRIPTION OF THE DRAWINGS

FIG. 1 is a perspective view of an exemplary extruded element for use as a housing for a hand-held electronic device, which has areas of bulk material to support areas of subsequent machining, in accordance with at least one aspect of the present invention;

FIG. 2 is a front plan view of the exemplary extruded element, illustrated in FIG. 1;

FIGS. 3A-3C are side plan and sectional side views of the exemplary extruded element, illustrated in FIG. 1, where each view represents the view from a different point along the length of the extrusion after the extruded element has been machined;

FIG. 4 is a perspective view of an exemplary extruded element for use as a housing for a hand-held electronic device, which has areas of bulk material to support areas of subsequent machining, in accordance with a further aspect of the present invention;

FIG. 5 is a top plan view of the exemplary extruded element, illustrated in FIG. 4;

FIG. 6 is a perspective view of the exemplary extruded element, illustrated in FIG. 4, after exemplary machining operations have been applied to the extruded element;

FIG. 7 is a perspective view of an exemplary extruded element for use as a housing for a hand-held electronic device, which has areas of bulk material to support areas of subsequent machining, in accordance with at least a still further aspect of the present invention; and

FIG. 8 is a flow diagram of a method for forming a housing for a hand-held electronic device, in accordance with at least one embodiment of the present invention.

### DETAILED DESCRIPTION OF THE PREFERRED EMBODIMENT(S)

While the present invention is susceptible of embodiment in various forms, there is shown in the drawings and will hereinafter be described presently preferred embodiments with the understanding that the present disclosure is to be considered an exemplification of the invention and is not intended to limit the invention to the specific embodiments illustrated.

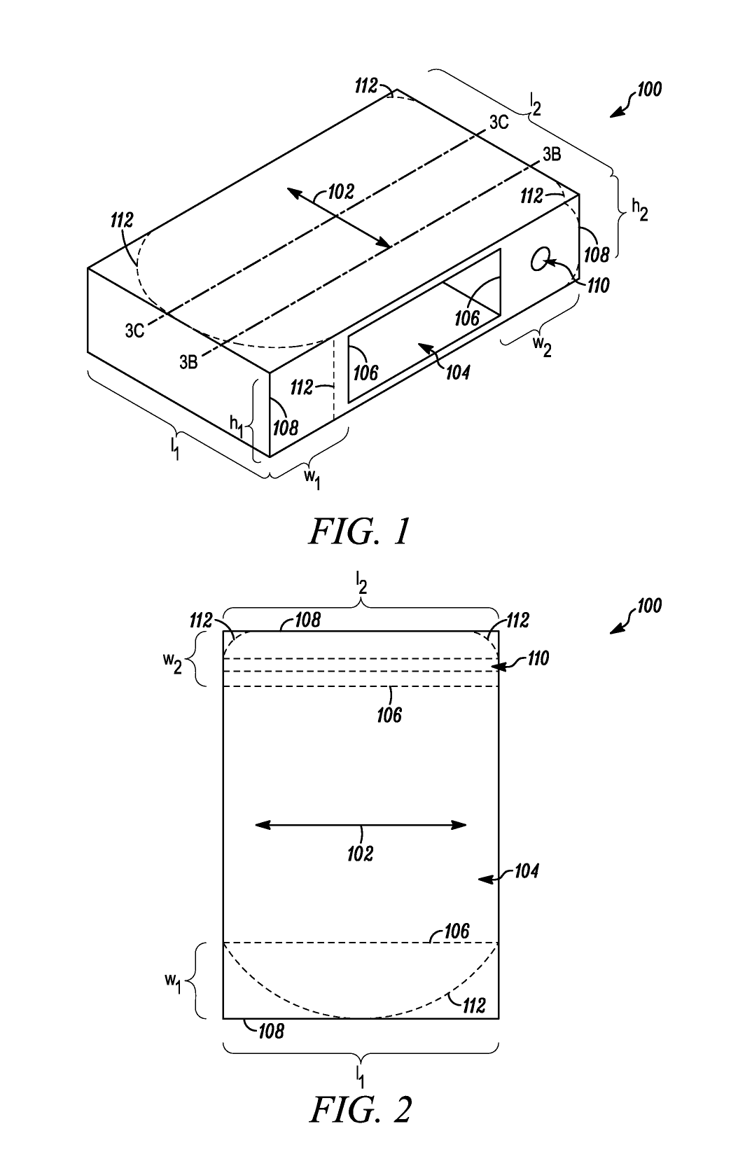

FIG. 1 illustrate a perspective view of an exemplary extruded element 100 for use as a housing for a hand-held electronic device, which has areas of bulk material to support areas of subsequent machining, in accordance with at least one aspect of the present invention. In connection with the illustrated embodiment, an arrow 102 defines a direction of extrusion. An extrusion has a profile, which is perpendicular to the direction of extrusion, that is generally uniform and defined by the size and shape of an opening in a die through which the extruded material is pushed and/or drawn. In the illustrated embodiment, the profile is represented by the surface illustrated in the figure, which has a rectangular opening 104. The rectangular opening 104 defines one end of an interior space, that runs the length of the extruded element 100.

In the embodiment illustrated, the opening 104 has two oppositely facing side surfaces 106, which stop well short of each of the respective outer ends 108 of the profile. The distance between the internal side surface 106 of the rectangular opening and the respective outer end 108 of the profile is larger than a typical wall thickness for a hollow tubular extrusion, and represents an area of bulk material having height h_{N}, width w_{N} and length l_{N}. The shape of the bulk material along the heightwise h_{N} direction and widthwise w_{N} direction represents the size and shape of the bulk material in the plane of the extruded material profile. The shape of the bulk material along the lengthwise l_{N} direction corresponds to the length of the extruded element 100, in the direction of extrusion.

In the illustrated embodiment, the heightwise direction extends along at least a portion of the profile's minor axis, and the widthwise direction extends along at least a portion of the profile's major axis. As such, in the illustrated embodiment, an area of bulk material is shown positioned at each end of the major axis, and extends the full height of the minor axis. In the example illustrated, the area of bulk material bounded by h₁, w₁ and l₁ is positioned proximate a bottom of the housing, and the area of bulk material bounded by h₂, w₂ and l₂ is positioned proximate a top of the housing for a hand-held electronic device. Examples of different types of hand-held electronic devices in which the teaching of the present invention might be applied include radio frequency (i.e. cellular) telephones, media (i.e. music) players, personal digital assistants, portable video gaming devices, cameras, and/or remote controls.

The bulk material provides an area where portions of the material can be selectively machined to produce one of multiple possible different types of shapes, while maintaining the continuity and/or integrity of the surface. In turn, this allows the profile of the extrusion to be modified, so as to be varied along the length of the extruded element 100, while continuing to maintain a substantially solid and/or continuous outer side surface proximate the area of bulk material and corresponding machining. However, the ability to maintain a substantially solid outer side surface does not preclude the intentional inclusion of openings, which might provide purposeful access between the exterior space and the interior space of the extruded element by other external elements.

While in some instances the bulk material might represent a substantially solid block of material corresponding to the respective portion of the profile along the length of the extruded element 100, in some instances the bulk material may incorporate purposefully placed voids in the profile which extend the length of the extruded element. For example, a cylindrical void 110 could be formed using a void forming feature such as a circular shaped pin or piercing mandrel appropriately arranged within the die through which the material is pushed or drawn through. Such a void might serve to produce a desired feature in an area of bulk material which might otherwise need to be made through a subsequent machining process, while still supporting a degree of subsequent machining that could be used to alter the shape of the profile along the length of the extrusion around the feature. Such voids can typically be associated with voids that are generally of a more uniform cross-sectional shape and having a largely consistent position within the extruded profile along the length of the extruded element 100.

In some instances it may be desirable to machine around the void 110, that is located within the bulk material, while maintaining the continuity of the remaining material around the void. In other instances, it may be desirable to machine into the area of the void 110, thereby exposing portions of the void at one or more locations along the length of the extruded element 100 in the direction of the extrusion. In at least some instances, the void 110 might be used to support a hinge structure, where a pin about which the extruded element 100 might rotate may be received. It is further possible that the void 110 might be produced through a subsequent machining process, as opposed to being formed as part of the extrusion process. Where the void is produced as part of a machining process, it would be possible that the feature could be partially added and/or for the feature to not run the full length of the extruded part in the direction of extrusion.

In FIG. 1, a set of dashed lines 112, represent an example of an area that might be machined away within the bulk material of the extruded element 100, that would allow for a machined surface that deviates from the contour of the originally extruded profile, as well as the contours of the corresponding top, bottom, front, back, and/or left or right side surfaces of the extruded element, but which maintains a substantially solid and/or continuous outer side surface, while avoiding the uniformity along the length of the extrusion that is common to extruded parts. In the present embodiment, as well as further embodiments, it is possible that some machining could additionally occur within the extruded element, such as from within the interior space defined at one of its end by opening 104. Internal machining could similarly serve to produce a varied profile of the extruded element 100 along the direction of extrusion 102.

In at least some embodiments, the machining might take the form of cutting, drilling, grinding, stamping, punching and/or etching away portions of the bulk material. In other words, in the context of the present invention, machining refers to a subsequently applied process that facilitates the further shaping of the extruded element through the removal of selective portions of the extruded element. While a exemplary list of possible machining processes has been provided, one skilled in the art will readily appreciate that still further forms of machining can be used in conjunction with the extruded element without departing from the teachings of the present invention. Furthermore, depending upon the type of material used as part of the original extrusion, material which is removed as part of the subsequent machining might be collected and reused in forming subsequent extrusions.

FIG. 2 illustrates a front plan view of the exemplary extruded element 100, illustrated in FIG. 1.

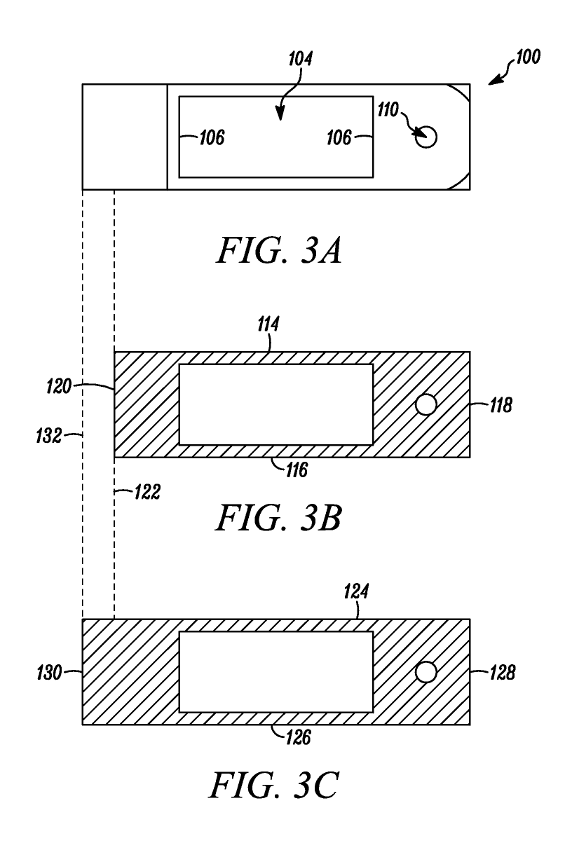

FIGS. 3A-3C illustrate side plan and sectional side views of the exemplary extruded element 100, illustrated in FIG. 1, where each view represents the plan or cross-sectional view from a different point along the length of extrusion after the extruded element has been machined. More specifically, FIG. 3A illustrates a side plan view, and FIGS. 3B and 3C each illustrate a cross-sectional side view at the point along the length of extrusion identified by the corresponding dashed line, illustrated in FIG. 1, after the identified sections 112 have been removed via a suitable machining process. The different cross-sectional side views illustrate a difference in the resulting profile of the extruded element 100 after the extruded element has been machined. After the exemplary machining, one of the more pronounced differences between the cross-sectional view illustrated in FIG. 3B and the cross-sectional view illustrated in FIG. 3C includes a difference in the length of the resulting profile along the major axis, where a portion of the bulk material at the bottom end of extruded element has been removed resulting in a profile at different points along the length of the extrusion having a more truncated or shortened length of the resulting outer perimeter. In FIG. 3B the outer perimeter is defined by a front surface 114, a back surface 116, a top surface 118, and a bottom surface 120, where the front and back surfaces extend to dashed line 122, as a result of the machining. In FIG. 3C the outer perimeter is defined by a front surface 124, a back surface 126, a top surface 128, and a bottom surface 130, with the front surface and the back surface extending to dashed line 132.

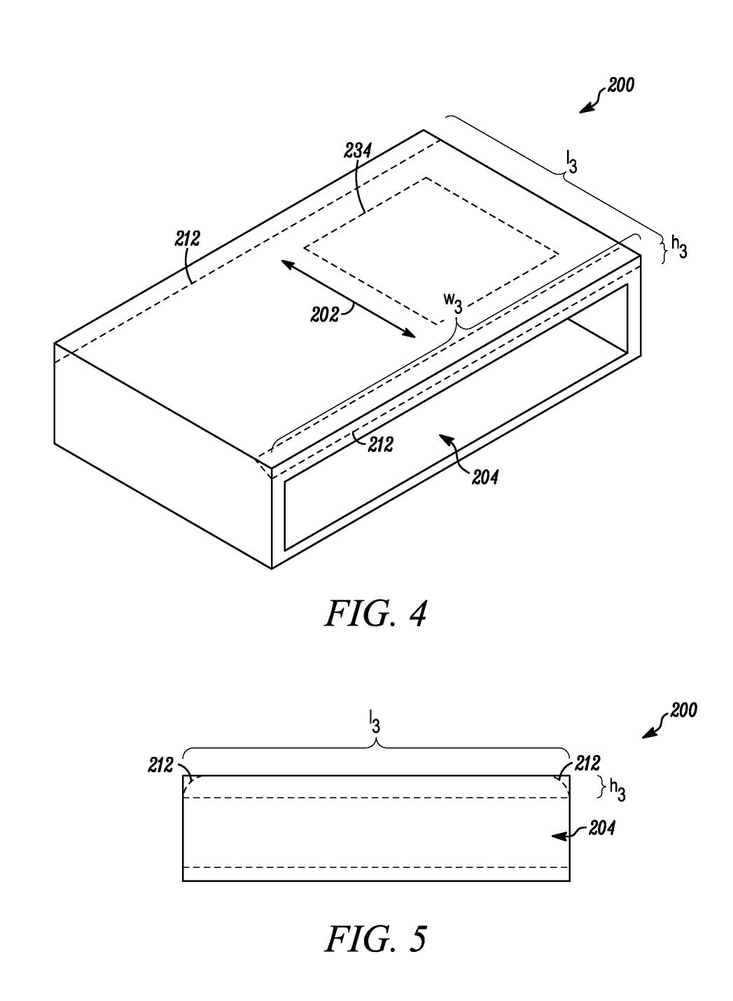

FIG. 4 illustrates a perspective view of an exemplary extruded element 200 for use as a housing for a hand-held electronic device, which has areas of bulk material to support areas of subsequent machining, in accordance with a further aspect of the present invention. Similar to arrow 102, illustrated in FIG. 1, arrow 202 defines a direction of extrusion. Further, similar to the extruded element 100 illustrated in FIG. 1, extruded element 200 has an opening 204 in the profile, which extends the length of the extrusion. However, whereas the extruded element 100 illustrated in FIG. 1 had areas of bulk material positioned within the profile at each end of the major axis, corresponding to the top and bottom of the housing for the hand-held device, extruded element 200 has an area of bulk material positioned with the profile at one end of the minor axis, and which runs the full length of the major axis, corresponding to the front of the housing for the hand-held device. More specifically, the area of bulk material is generally defined by a height h₃, width W₃ and length l₃.

Correspondingly, dashed lines 212 represent an example of an area, that might be machined away, in order to produce desired variability in the profile of the extruded element 200 at different points along the length of the of the extruded element. The extruded element 200 includes a second set of dashed lines 234, which coincides with the area of bulk material and which bounds an area of material which is intended to be removed. However, while technically the removal of material bounded by the second set of dashed lines 234, would alter the shape of the extruded element 200, the removal of area is less about altering the shape of the housing of the electronic device, and more about providing access between the exterior space and the interior space formed by the opening 204 in the profile that extends the length of the extrusion. Separate from additional surface contouring through machining of the external surface in and around the opening formed by the removal of material bounded by dashed lines 234, the removal of this material is not seen as meaningfully affecting the outer circumference of the profile at a point along the length of the extrusion where the opening intersects. In other words, providing an access opening is not viewed as altering the profile of the extruded element as the surface is generally defined by the contour at the edge of the opening. In many instances, an electronic and/or electromechanical element such as a keypad or a display element will be intended to be positioned within the opening.

Alternatively, in removing the material bounded by dashed lines 212, the overall feeling of shape associated with the profile of the extruded element is altered along the direction of extrusion, thereby avoiding the very straight and/or uniform appearance commonly associated with an extruded element at least in the direction of extrusion.

FIG. 5 illustrates another view of the exemplary extruded element 200, illustrated in FIG. 4, namely a top plan view. In essence, the additional view provides another perspective in which the features illustrated in FIG. 4 can be appreciated. More specifically from the top view, the area of bulk material corresponding to its length and height is readily discernable, as well as the area of the material bounded by the dashed lines 212, which is intended to be removed for purposes of shaping the extruded element 200, in such a way that the resulting profile at different points along the length of the extrusion might differ.

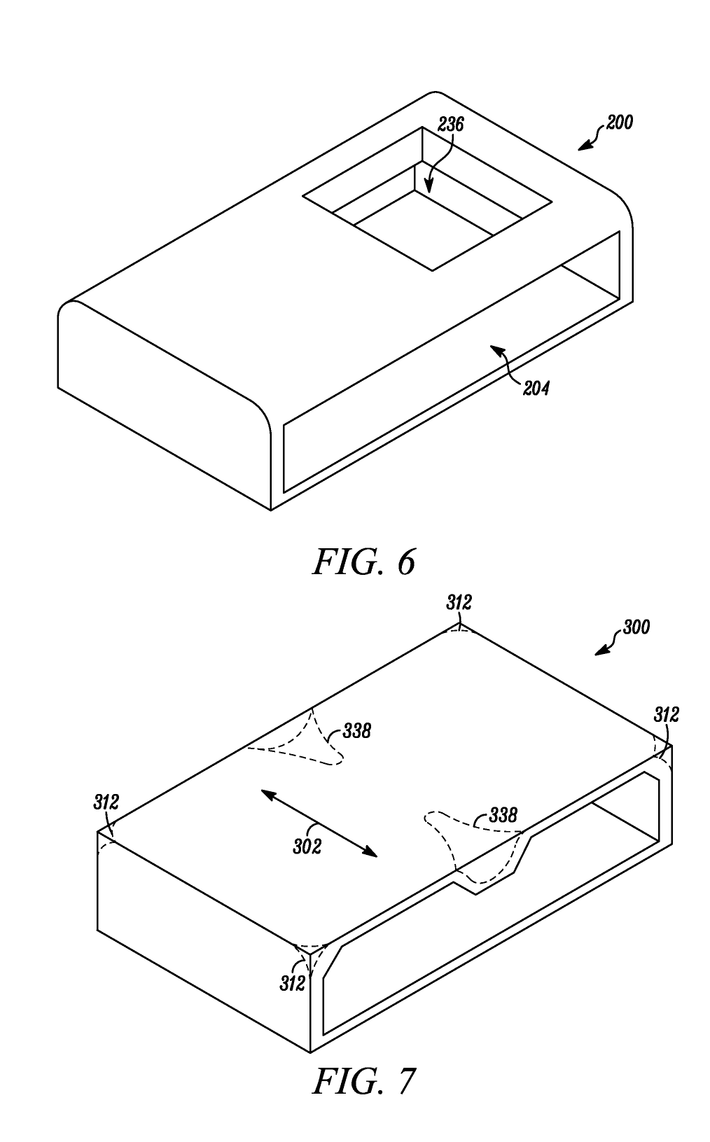

FIG. 6 illustrates a perspective view of the exemplary extruded element 200, illustrated in FIG. 4, after exemplary machining operations have been applied to the extruded element 200, which not only shape the extruded element so as to alter the profile at different points in the direction of extrusion, but also provide access via an opening 236 between the external and internal space of the extruded element 200, as discussed above.

FIG. 7 illustrates a perspective view of an exemplary extruded element 300, which similarly could be used as a housing for a hand-held electronic device, which has areas of bulk material to support areas of subsequent machining, in accordance with at least a still further aspect of the present invention. Whereas the bulk material in each of the previous two examples extended the entire width or height of either the major axis or the minor axis of the profile, it is noted that there is no requirement for the bulk area to extend the full width or height of the profile, and support an area of bulk material which can be machined for purposes of altering the profile along the length of the extruded element. More specifically, in the illustrated embodiment, an area of bulk material is present in each of the corners of the profile, which could correspond to both a top and a bottom of a front of a housing of a hand-held electronic device. In this way, bulk material is available to allow for machining of an area 312, which might be used to shape the corresponding corners and/or top or bottom front edge of the housing.

In the illustrated embodiment, an additional area of bulk material is positioned near the center (relative to the major axis) of the profile toward a front side of the extruded element 300. In this way, an area 338 proximate the center of the major axis toward the front of the extruded element 300 could be machined to enable shaping of the extruded element such that the profile might vary at different points along the length of the extruded element in the direction of extrusion 302.

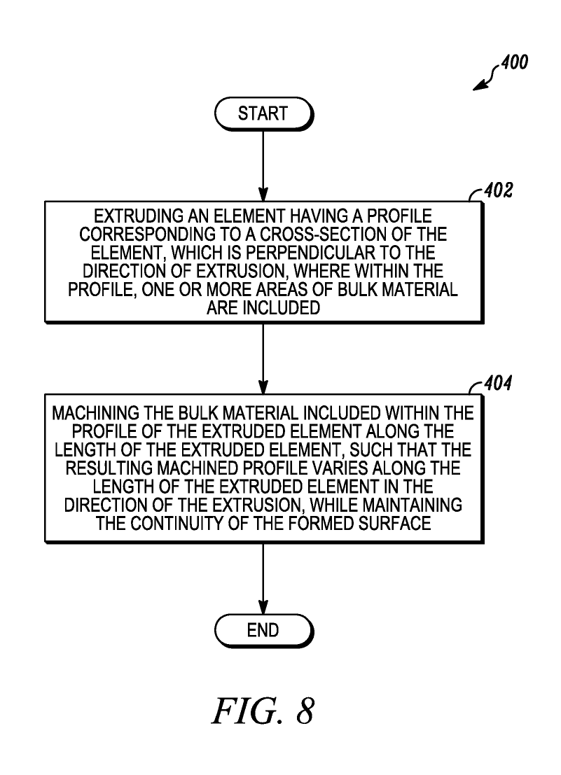

FIG. 8 illustrates a flow diagram of a method 400 for forming a housing for a hand-held electronic device, in accordance with at least one embodiment of the present invention. The method includes extruding 402 an element having a profile corresponding to a cross-section of the element of the element, which is substantially perpendicular to the direction of extrusion, where within the profile, one or more areas of bulk material are included. The bulk material included within the profile of the extruded element is then machined 404 along the length of the extruded element, such that the resulting machined profile varies along the length of the extruded element in the direction of extrusion, while maintaining the continuity of the formed surface.

In at least some instances, the variance of the machined profile will correspond to a variance in the outer perimeter of the machined profile that defines the outer surface of the extruded element, which in turn defines the outer surface of the housing for a hand-held electronics device. In still further instances, the machining may include machining of openings into the formed surface for providing access between the space external to the extruded element and space internal to the extruded element, thereby providing access to any components located therein.

One skilled in the art will recognize that the bulk area and the corresponding machining can take many different forms, without departing from the teachings of the present invention. For example, the bulk area can be located in other portions of the profile, and can include both portions that extend along each of portions of the minor axis and the major axis either separately or at the same time.

While the preferred embodiments of the invention have been illustrated and described, it is to be understood that the invention is not so limited. Numerous modifications, changes, variations, substitutions and equivalents will occur to those skilled in the art without departing from the spirit and scope of the present invention as defined by the appended claims.

What is claimed is:

1. A housing for a hand-held electronic device comprising:
an extruded element having a profile corresponding to a cross-section of the element, which is perpendicular to the direction of extrusion, the extruded element including within the profile, one or more areas of bulk material; and
the one or more areas of the bulk material comprising a machined surface along the length of the extruded element in the direction of the extrusion including a resulting machined profile which varies along the length of the extruded element in the direction of extrusion, while maintaining the continuity of the formed surface.

2. A housing for a hand-held electronic device in accordance with claim 1, wherein the resulting machined profile which varies along the length of the extruded element includes an outer perimeter, which varies along the length of the extruded element.

3. A housing for a hand-held electronic device in accordance with claim 2, wherein the outer perimeter of the resulting machined profile along the length of the extruded element defines the outer surface of the housing for the hand-held electronic device, which includes the formed surface.

4. A housing for a hand-held electronic device in accordance with claim 3, wherein the outer surface includes machined openings to create access from outside of the device to internally placed components.

5. A housing for a hand-held electronic device in accordance with claim 1, wherein the profile of the extruded element has a major axis which extends in a first direction and a minor axis which extends in a second direction which is substantially perpendicular to the first direction, and wherein the amount that the profile extends in the direction of the major axis is greater than the amount that the profile extends in the direction of the minor axis.

6. A housing for a hand-held electronic device in accordance with claim 5, wherein the length of the extruded element in the direction of extrusion is less than the amount that the profile extends in the direction of the major axis.

7. A housing for a hand-held electronic device in accordance with claim 5, wherein the one or more areas of bulk material include an area of bulk material positioned within the profile at one or more ends of the major axis and extends in the direction of the minor axis.

8. A housing for a hand-held electronic device in accordance with claim 7, wherein the area of bulk material positioned within the profile at one or more ends of the major axis extends the full width of profile along the minor axis.

9. A housing for a hand-held electronic device in accordance with claim 7, wherein the area of bulk material positioned within the profile at one or more ends of the major access and extends in the direction of the minor axis each correspond to one of a top or a bottom of the hand-held electronic device.

10. A housing for a hand-held electronic device in accordance with claim 7, wherein the area of bulk material positioned within the profile at one of the one or more ends of the major axis and extends in the direction of the minor axis has an opening which extends in the direction of the extrusion.

11. A housing for a hand-held electronic device in accordance with claim 5, wherein the one or more areas of bulk material include an area of bulk material positioned within the profile at one or more ends of the minor axis, which extend in the direction of the major axis.

12. A housing for a hand-held electronic device in accordance with claim 11, wherein the area of bulk material positioned within the profile at one or more ends of the minor axis and which extend in the direction of the major axis each corresponds to one of the front or back of the hand-held electronic device.

13. A hand-held electronic device including a housing comprising:
an extruded element having a profile corresponding to a cross-section of the element, which is perpendicular to the direction of extrusion, the extruded element including within the profile, one or more areas of bulk material; and
the one or more areas of the bulk material comprising a machined surface along the length of the extruded element in the direction of the extrusion including a resulting machined profile which varies along the length of the extruded element in the direction of extrusion, while maintaining the continuity of the formed surface.

14. A hand-held electronic device in accordance with claim 13, wherein the resulting machined profile which varies along the length of the extruded element includes an outer perimeter of the resulting machined profile, which varies along the length of the extruded element, and defines the outer surface of the housing for the hand-held electronic device, which includes the formed surface.

15. A hand-held electronic device in accordance with claim 14, wherein the outer surface includes machined openings to create access from outside of the device to internally placed components.

16. A hand-held electronic device in accordance with claim 13, wherein the profile of the extruded element has a major axis which extends in a first direction and a minor axis which extends in a second direction which is substantially perpendicular to the first direction, and wherein the amount that the profile extends in the direction of the major axis is greater than the amount that the profile extends in the direction of the minor axis, where the length of the extruded element in the direction of extrusion is less than the amount that the profile extends in the direction of the major axis.

17. A hand-held electronic device in accordance with claim 13, wherein the hand-held electronic device is a wireless communication device.

18. A hand-held electronic device in accordance with claim 17, wherein the wireless communication device is a cellular radio telephone.

19. A method for forming a housing for a hand-held electronic device comprising:
extruding an element having a profile corresponding to a cross-section of the element, which is perpendicular to the direction of extrusion, where within the profile, one or more areas of bulk material are included; and
machining the bulk material included within the profile of the extruded element along the length of the extruded element, such that the resulting machined profile varies along the length of the extruded element in the direction of the extrusion, while maintaining the continuity of the formed surface.

20. A method for forming a housing for a hand-held electronic device in accordance with claim 19, wherein the resulting machined profile which varies along the length of the extruded element includes an outer perimeter, which varies along the length of the extruded element, which defines the outer surface of the housing for the hand-held electronic device, that includes the formed surface.

21. A method for forming a housing for a hand-held electronic device in accordance with claim 20, further comprising machining openings into the formed surface for creating access from outside of the device to internally placed components.
